(19) United States
(12) Patent Application Publication
(10) Pub. No.: US 2025/0359064 A1
(43) Pub. Date: Nov. 20, 2025

(54) MEMORY DEVICE AND METHOD OF MANUFACTURING THE MEMORY DEVICE

(71) Applicant: SK hynix Inc., Icheon-si Gyeonggi-do (KR)

(72) Inventors: Sung Soo AHN, Icheon-si Gyeonggi-do (KR); Se Hyeong KIM, Icheon-si Gyeonggi-do (KR); Ji Heon KIM, Icheon-si Gyeonggi-do (KR); Seung Hun CHOI, Icheon-si Gyeonggi-do (KR)

(73) Assignee: SK hynix Inc., Icheon-si Gyeonggi-do (KR)

(21) Appl. No.: 18/928,789

(22) Filed: Oct. 28, 2024

(30) Foreign Application Priority Data
May 14, 2024 (KR) 10-2024-0063223

(51) Int. Cl. H10B 43/50; H10B 43/10; H10B 43/27

(52) U.S. Cl. CPC H10B 43/50; H10B 43/10; H10B 43/27

(57) ABSTRACT

Provided herein may be a memory device and a method of manufacturing the same. The memory device may include a cell region and a connection region arranged adjacent to each other in a first direction, a stacked structure formed in the cell region and the connection region, a first slit vertically passing through the stacked structure in the cell region and extending in the first direction, a second slit vertically passing through the stacked structure in the connection region and extending in the first direction, and a slit separation structure vertically penetrating the stacked structure at a boundary portion between the cell region and the connection region.

### CROSS-REFERENCE TO RELATED APPLICATION

The present application claims priority under 35 U.S.C. § 119(a) to Korean patent application number 10-2024-0063223 filed on May 14, 2024, in the Korean Intellectual Property Office, the entire contents of which application is incorporated herein by reference.

### BACKGROUND

### 1. Technical Field

Various embodiments of the present disclosure generally relate to a memory device and a method of manufacturing the memory device, and more particularly to a memory device including a slit and a method of manufacturing the memory device.

### 2. Related Art

A memory device may include a memory cell array in which data is stored, a peripheral circuit which performs a program operation, a read operation, or an erase operation, and a control logic which controls the peripheral circuit.

The memory cell array may include a plurality of memory blocks, each of which may include a plurality of memory cells. A memory device having a three-dimensional (3D) structure may include memory cells stacked on a substrate. For example, in the memory device having a 3D structure, each of memory blocks may include a plurality of strings extending from a substrate in a vertical direction. Also, each of the plurality of strings may include a plurality of memory cells.

The memory blocks may be separated from each other by a slit. The slit may be a trench which separates stack layers in the form of a line. As the storage capacity of the memory device increases, the height of the stack layers may increase. Further, structures included in the stack layers may have density differences. Because an etching process is performed in a plasma environment, differences may occur in a charge potential as the height and density differences of an etching target structure increase, thus causing defects in the slit.

### SUMMARY

Various embodiments of the present disclosure are directed to a memory device. The memory device may include a cell region and a connection region arranged adjacent to each other in a first direction, a stacked structure formed in the cell region and the connection region, a first slit vertically passing through the stacked structure in the cell region and extending in the first direction, a second slit vertically passing through the stacked structure in the connection region and extending in the first direction, and a slit separation structure vertically penetrating the stacked structure at a boundary portion between the cell region and the connection region.

An embodiment of the present disclosure may provide for a memory device. The memory device may include a first memory block including a cell region and a connection region separated from each other in a first direction, a second memory block including the cell region and the connection region separated from each other in the first direction, the second memory block being arranged adjacent to the first memory block in a second direction substantially perpendicular to the first direction, a slit configured to separate the first and second memory blocks from each other, and a slit separation structure vertically extending between a boundary portion between the cell region and the connection region of the first memory block and a boundary portion between the cell region and the connection region of the second memory block, and penetrating a portion of the slit.

An embodiment of the present disclosure may provide for a method of manufacturing a memory device. The method may include forming a first stacked structure on a lower structure in which a cell region and a connection region adjacent to each other share a common border, forming first holes that vertically pass through the first stacked structure in the cell region, forming a second stacked structure on the first stacked structure, forming second holes coupled to the first holes by vertically passing through the second stacked structure in the cell region, forming cell plugs in the first holes and the second holes, forming a slit separation structure that vertically penetrates the second stacked structure and the first stacked structure in the connection region, and forming a first slit that passes through the second stacked structure and the first stacked structure in the cell region and a second slit that passes through the second stacked structure and the first stacked structure in the connection region, wherein the first slit and the second slit are located on an identical line and are physically spaced apart from each other by the slit separation structure.

An embodiment of the present disclosure may provide for a method of manufacturing a memory device. The method may include forming a first stacked structure on a lower structure in which a cell region and a connection region adjacent to each other share a common border, forming first holes that vertically pass through the first stacked structure in the cell region, forming a slit separation structure that vertically penetrates the first stacked structure in the connection region, forming a second stacked structure on the first stacked structure, forming second holes coupled to the first holes by vertically passing through the second stacked structure in the cell region, forming cell plugs in the first holes and the second holes, and forming a slit that passes through the second stacked structure and the first stacked structure in the cell region and the connection region, wherein the slit separation structure penetrates a portion of the slit.

### BRIEF DESCRIPTION OF THE DRAWINGS

FIG. 1 is a diagram illustrating a memory device.

FIG. 2 is a diagram illustrating an arrangement relationship between memory blocks and a peripheral circuit.

FIG. 3 is a view illustrating the structure of a memory block.

FIG. 4 is a plan view illustrating a memory device according to a first embodiment of the present disclosure.

FIGS. 5A and 5B are a perspective view and a sectional view of a memory device according to a second embodiment of the present disclosure.

FIGS. 6A, 6B, 6C, 6D, 6E, 6F, 6G, and 6H are sectional views and plan views illustrating a method of manufacturing a memory device according to first embodiments of the present disclosure.

FIGS. 7A, 7B, 7C, and 7D are sectional views and plan views illustrating a method of manufacturing a memory device according to second embodiments of the present disclosure.

FIG. 8 is a diagram illustrating a memory system according to an embodiment of the present disclosure.

FIG. 9 is a diagram illustrating an embodiment of a memory system.

FIG. 10 is a diagram illustrating an embodiment of a memory system.

FIG. 11 is a diagram illustrating an embodiment of a memory system.

FIG. 12 is a diagram illustrating an embodiment of a memory system.

### DETAILED DESCRIPTION

Specific structural or functional descriptions, disclosed herein, are exemplified to describe embodiments according to the concept of the present disclosure. The embodiments according to the concept of the present disclosure should not be construed as being limited to embodiments described below, and may be modified in various forms and replaced with other equivalent embodiments.

Hereinafter, although the terms “first” and “second” may be used herein to describe various elements, these elements should not be limited by these terms. The terms are used to distinguish one element from other elements. It will be understood that when an element or layer etc., is referred to as being “on,” “connected to” or “coupled to” another element or layer etc., it can be directly on, connected or coupled to the other element or layer etc., or intervening elements or layers etc., may be present. In contrast, when an element or layer etc., is referred to as being “directly on,” “directly connected to” or “directly coupled to” another element or layer etc., there are no intervening elements or layers etc., present. Terms such as “vertical,” “horizontal,” “over,” “top”, “side,” “lower,” “outer” and other terms implying relative spatial relationship or orientation are utilized only for the purpose of ease of description or reference to a drawing and are not otherwise limiting. The cross-hatching throughout the figures illustrates corresponding or similar areas between the figures rather than indicating the materials associated with the areas.

Various embodiments of the present disclosure are directed to a memory device and a method of manufacturing the memory device, which can prevent or mitigate defects from occurring in a slit.

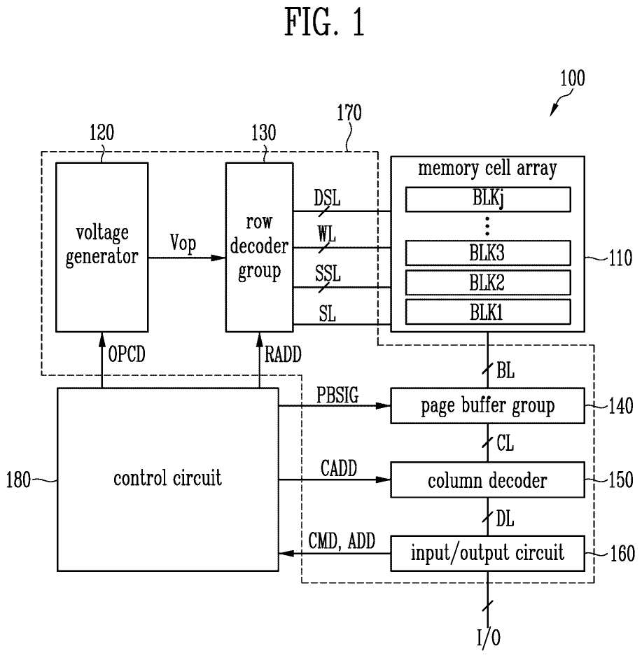

FIG. 1 is a diagram illustrating a memory device.

Referring to FIG. 1, a memory device 100 may include a memory cell array 110, a peripheral circuit 170, and a control circuit 180.

The memory cell array 110 may include first to j-th memory blocks BLK1 to BLKj. Each of the first to j-th memory blocks BLK1 to BLKj may include memory cells. Each of the memory blocks may be formed in a three-dimensional (3D) structure. The memory blocks having a 3D structure may include memory cells vertically stacked on a substrate. Drain select lines DSL, word lines WL, and source select lines SSL may be connected to each of the first to j-th memory blocks BLK1 to BLKj, and bit lines BL may be connected in common to the first to j-th memory blocks BLK1 to BLKj.

According to a program scheme, each memory cell may store 1 bit of data or 2 or more bits of data. For example, a scheme for storing 1 bit of data in one memory cell is referred to as a single-level cell (SLC) scheme, and a scheme for storing 2 bits of data in one memory cell is referred to as a multi-level cell (MLC) scheme. A scheme for storing 3 bits of data in one memory cell is referred to as a triple-level cell (TLC) scheme, and a scheme for storing 4 bits of data in one memory cell is referred to as a quad-level cell (QLC) scheme. In addition, 5 or more bits of data may be stored in one memory cell.

The peripheral circuit 170 may perform a program operation of storing data in the memory cell array 110, a read operation of outputting data stored in the memory cell array 110, and an erase operation of erasing data stored in the memory cell array 110. For example, the peripheral circuit 170 may include a voltage generator 120, a row decoder 130, a page buffer group 140, a column decoder 150, and an input/output circuit 160.

The voltage generator 120 may generate various operating voltages Vop that are used for a program operation, a read operation, or an erase operation in response to an operation code OPCD. For example, the voltage generator 120 may generate a program voltage, a pass voltage, a turn-on voltage, a turn-off voltage, a ground voltage, a negative voltage, a source voltage, a verify voltage, a read voltage, an erase voltage, a precharge voltage, etc. in response to the operation code OPCD. The program voltage may be a voltage that is applied to a word line selected from among the word lines WL during a program operation, and may be used to increase the threshold voltages of memory cells connected to the selected word line. The pass voltage may be a voltage that is applied to unselected word lines among the word lines WL during a program or read operation, and may be used to turn on memory cells coupled to the unselected word lines. The turn-on voltage may be a voltage that is applied to the drain select lines DSL or the source select lines SSL, and may be used to turn on drain select transistors or source select transistors. The turn-off voltage may be a voltage that is applied to the drain select lines DSL or the source select lines SSL, and may be used to turn off drain select transistors or source select transistors. The ground voltage may be a voltage of 0 V. The negative voltage may be a voltage lower than 0 V. The source voltage may be a voltage that is applied to the source line SL, and may be a negative voltage, a ground voltage or a positive voltage. The verify voltage may be a voltage for determining the threshold voltages of selected memory cells during a program operation or an erase operation, and may be applied to the selected word line or all word lines connected to a selected memory block. The read voltage may be a voltage that is applied to the selected word line during a read operation, and may be used to determine data stored in memory cells. The erase voltage may be a voltage that is applied to the source line SL during an erase operation, and may be used to decrease the threshold voltages of the memory cells. The precharge voltage may be a positive voltage for precharging the channels of unselected strings during a program operation, and may be supplied to the source line SL.

The row decoder 130 may be connected to the voltage generator 120 through global lines GL, and may be connected to the first to j-th memory blocks BLK1 to BLKj through the drain select lines DSL, the word lines WL, the source select lines SSL, and the source line SL. For example, the row decoder 130 may transmit the operating voltages Vop to the drain select lines DSL, the word lines WL, the source select lines SSL, and the source line SL, which are connected to a memory block selected according to a row address RADD.

The page buffer group 140 may include a plurality of page buffers (not illustrated) connected to the bit lines BL, respectively. The page buffers (not illustrated) may be connected to the memory blocks through the bit lines BL. The page buffers (not illustrated) may adjust the levels of voltages to be applied to the bit lines BL and times at which the voltages are applied to the bit lines BL in response to the page buffer control signals PBSIG, and may store data read from the memory cells by sensing the currents or voltages of the bit lines BL. During a program operation, the page buffers (not illustrated) may apply a program-enable voltage, a program-inhibit voltage or a precharge voltage to the bit lines BL. The program-enable voltage may be set to 0 V or a negative voltage. The program-inhibit voltage may be set to a positive voltage.

The column decoder 150 may be configured such that data is transferred between the page buffer group 140 and the input/output circuit 160 in response to a column address CADD. For example, the column decoder 150 may be connected to the page buffer group 140 through column lines CL, and may be connected to the input/output circuit 160 through the data lines DL.

The input/output circuit 160 may receive or output a command CMD, an address ADD, or data through input/output lines I/O. For example, the input/output circuit 160 may transmit the command CMD and the address ADD, received from an external controller through the input/output lines I/O, to the control circuit 180, and may transmit the data, received from the external controller through the input/output lines I/O, to the column decoder 150. Alternatively, the input/output circuit 160 may output data, received from the column decoder 150, to the external controller through the input/output lines I/O.

The control circuit 180 may output the operation code OPCD, the row address RADD, the page buffer control signals PBSIG, and the column address CADD in response to the command CMD and the address ADD. For example, when the command CMD input to the control circuit 180 is a command corresponding to a program operation, the control circuit 180 may control the peripheral circuit 170 to perform the program operation on a memory block selected according to the address ADD. When the command CMD input to the control circuit 180 is a command corresponding to a read operation, the control circuit 180 may control the peripheral circuit 170 to perform the read operation on a memory block selected according to the address and output the read data. When the command CMD input to the control circuit 180 is a command corresponding to an erase operation, the control circuit 180 may control the peripheral circuit 170 to perform the erase operation on a selected memory block.

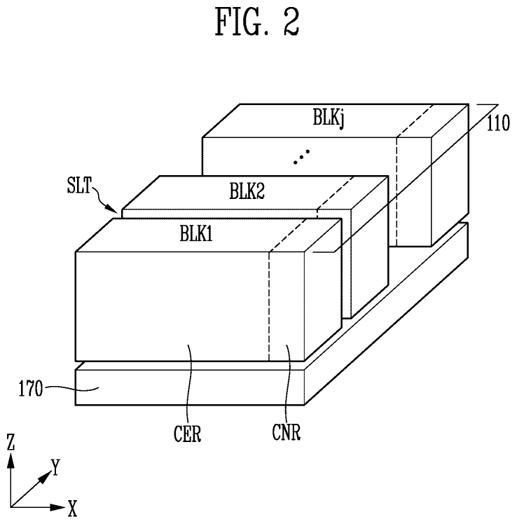

FIG. 2 is a diagram illustrating an arrangement relationship between memory blocks and a peripheral circuit.

Referring to FIG. 2, a memory cell array may include first to j-th memory blocks BLK1 to BLKj. The first to j-th memory blocks BLK1 to BLKj may be stacked on the peripheral circuit 170. For example, the first to j-th memory blocks BLK1 to BLKj may be arranged in a second horizontal direction Y. For example, the peripheral circuit 170 may be arranged on a substrate, and the first to j-th memory blocks BLK1 to BLKj may be arranged on the peripheral circuit 170. That is, the peripheral circuit 170 may be disposed between the first to j-th memory blocks BLK1 to BLKj and the substrate.

Because the first to j-th memory blocks BLK1 to BLKj and the peripheral circuit 170 are disposed in a vertical direction Z, each of the first to j-th memory blocks BLK1 to BLKj may include a cell region CER and a connection region CNR. For example, the cell region CER and the connection region CNR may be arranged in a first horizontal direction. The cell region CER may include memory cells, and the connection region CNR may include contacts coupled to the peripheral circuit 170. In an embodiment, a slit SLT may be formed between each of the first to j-th memory blocks BLK1 to BLKj.

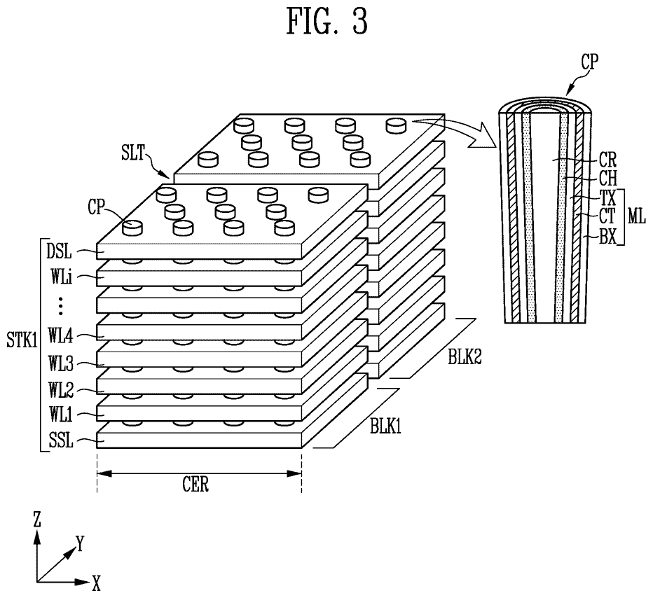

FIG. 3 is a view illustrating the structure of a memory block.

Referring to FIG. 3, first and second memory blocks BLK1 and BLK2 arranged in a Y direction are illustrated by way of example. The first and second memory blocks BLK1 and BLK2 are configured in the same manner, and thus the structure of the first memory block BLK1 will be described in detail below.

The first memory block BLK1 may include a first stacked structure STK1 including a source select line SSL, first to i-th word lines WL1˜WLi, and a drain select line DSL, which are vertically stacked on a lower structure (not illustrated), and cell plugs CP vertically penetrating the first stacked structure STK1. A lower structure (not illustrated) may be a substrate, a peripheral circuit or a source line. The cell plugs CP may be formed in the cell region CER. As used herein, the tilde “˜” indicates a range of components. For example, “WL1˜WLi” indicates the inverters WL1, WL2, . . . , and WLi shown in FIG. 3.

Each of the cell plugs CP may include a memory layer ML, a channel layer CH, and a core pillar CR. The memory layer ML may include a blocking layer BX, a charge trap layer CT, and a tunnel isolation layer TX. The blocking layer BX may be formed in the shape of a cylinder penetrating the first stacked structure STK1, and may be formed of an oxide layer or a silicon oxide layer. The charge trap layer CT may be formed in a cylindrical shape along an inner wall of the blocking layer BX, and may be formed of a nitride layer. The tunnel isolation layer TX may be formed in a cylindrical shape along an inner wall of the charge trap layer CT, and may be formed of an oxide layer or a silicon oxide layer. The channel layer CH may be formed in a cylindrical shape along an inner wall of the tunnel isolation layer TX, and may be formed of conductive polysilicon. The core pillar CR may be formed in the shape of a cylinder filling the channel layer CH, and may be formed of an insulating material such as an oxide layer or a silicon oxide layer. The memory layer ML adjacent to the first to i-th word lines WL1 to WLi may form the memory cells, the memory layer ML adjacent to the source select line SSL may form a source select transistor, and the memory layer ML adjacent to the drain select line DSL may form a drain select transistor.

The first and second memory blocks BLK1 and BLK2 may be separated as different blocks by a slit SLT. The slit SLT may be a trench formed in a line shape between the first and second memory blocks BLK1 and BLK2. Each of the source select line SSL, the first to i-th word lines WL1 to WLi, and the drain select line DSL included in the first and second memory blocks BLK1 and BLK2 may be separated by the slit SLT.

Insulating layers may be formed on sidewalls of the slit SLT to face each other, and a source contact may be formed between the insulating layers. For example, when the source line is formed under the first and second memory blocks BLK1 and BLK2, the source contact may be formed in the slit SLT, and may be coupled to the source line.

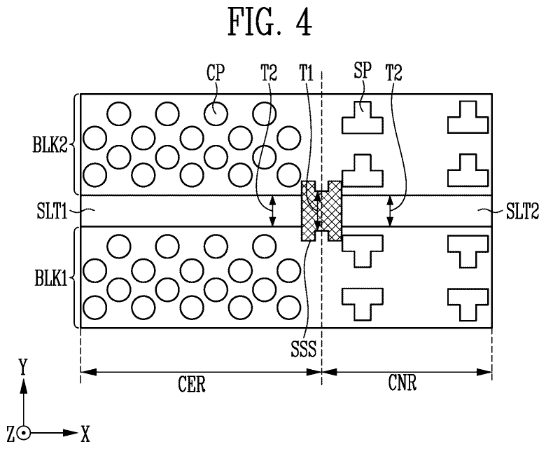

FIG. 4 is a plan view illustrating a memory device according to a first embodiment of the present disclosure.

Referring to FIG. 4, cell plugs CP may be included in a cell region CER of each of first and second memory blocks BLK1 and BLK2, and support patterns SP which prevent or mitigate a stacked structure from tilting may be included in a connection region CNR thereof. The support patterns SP may be formed of an insulating material or a conductive material, and may vertically penetrate the stacked structure in the same manner as the cell plugs CP. Also, in the connection region CNR, a plurality of contact plugs (not illustrated) vertically penetrating the stacked structure may be formed.

The cell plugs CP may contain a conductive material, and the support patterns SP may be formed of a conductive material or an insulating material. Although memory cells configured to store data are included in the cell region CER, the patterns supporting the stacked structure are formed in the connection region CNR, and thus the density of the cell plugs CP included in the cell region CER may be higher than the density of the support patterns SP included in the connection region CNR. In an embodiment, the cell region CER and the connection region CNR may be arranged adjacent to each other in a first direction (i.e., X). For example, the cell region CER may share a common border with the connection region CNR as shown in FIG. 4.

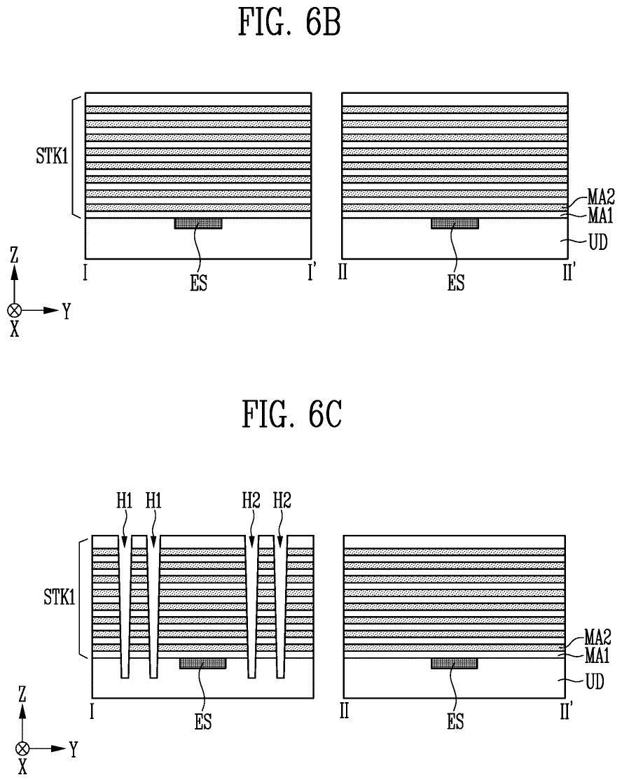

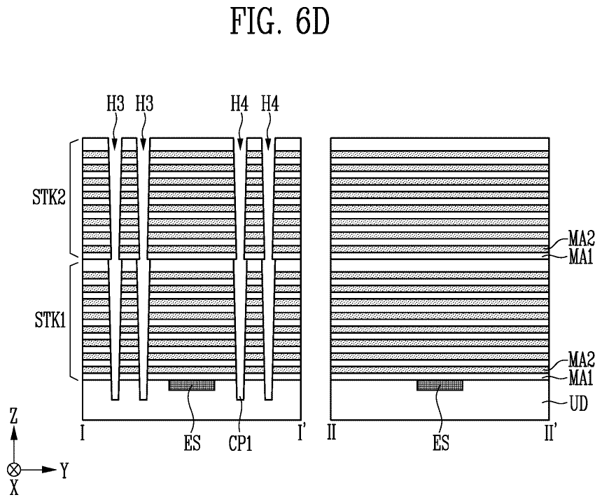

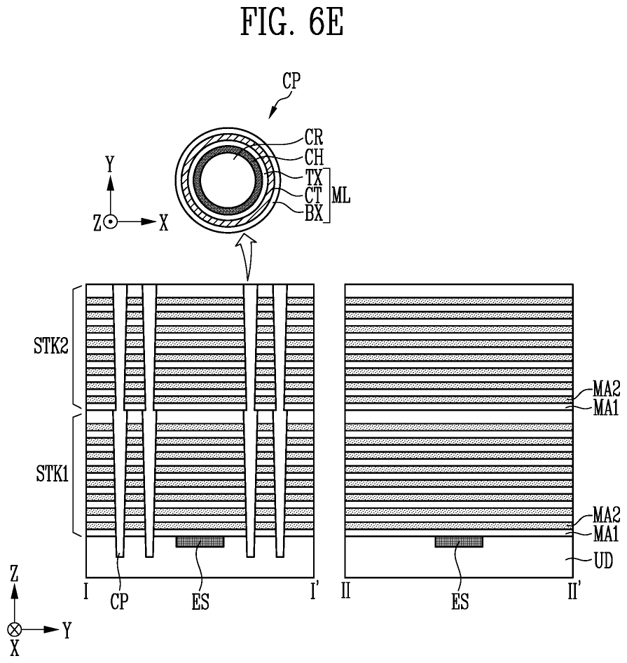

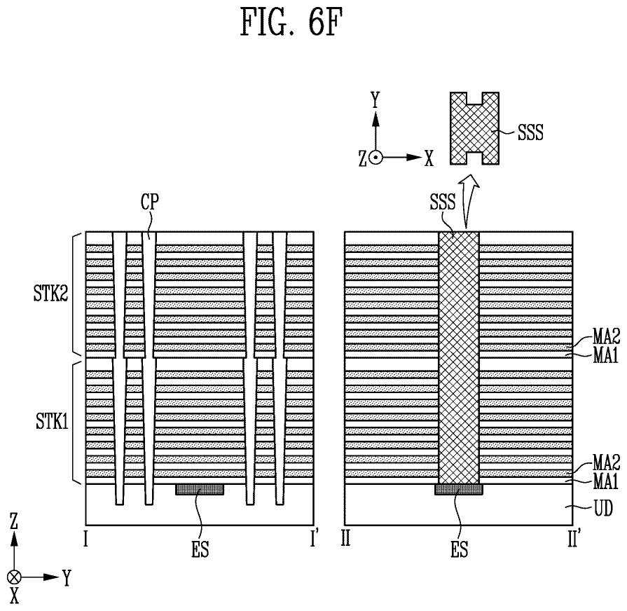

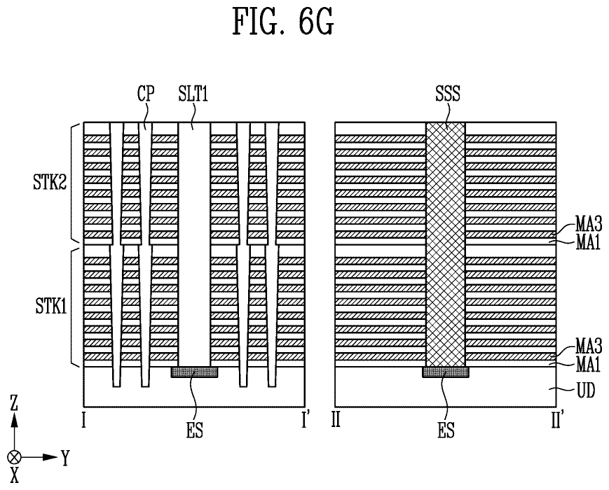

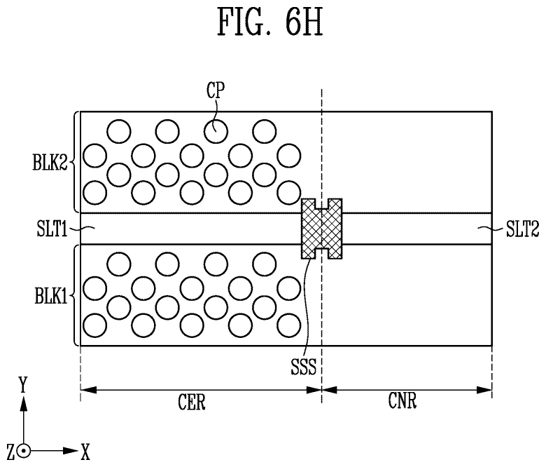

The first memory block BLK1 and the second memory block BLK2 may be physically spaced apart from each other by a first slit SLT1 and a second slit SLT2. The first slit SLT1 and the second slit SLT2 may be disposed on the same line (i.e., collinear), and may be physically spaced apart from each other by a slit separation structure SSS. For example, the first slit SLT1 may be disposed between the cell region CER of the first memory block BLK1 and the cell region CER of the second memory block BLK2, and the second slit SLT2 may be disposed between the connection region CNR of the first memory block BLK1 and the connection region CNR of the second memory block BLK2. The slit separation structure SSS may be disposed between a boundary portion between the cell region CER and the connection region CNR of the first memory block BLK1 and a boundary portion between the cell region CER and the connection region CNR of the second memory block BLK2. The slit separation structure SSS may extend in a vertical direction. In an embodiment, the vertical direction may be the stacking direction of the first and second material layers MA1 and MA2 as shown in FIG. 6B. For example, the Z direction may be the vertical direction. As such, the first slit SLT1 may vertically pass through the stacked structure STK (i.e., STK1 and/or STK2) in the cell region CER and extend in the first direction X. Also, the second slit SLT2 may vertically pass through the stacked structure STK (i.e., STK1 and/or STK2) in the cell region CER and extend in the first direction X. In an embodiment, the slit separation structure SSS extends from the cell region CER over a boundary portion between the cell region CER and the connection region CNR and into the connection region CNR. Thus, in an embodiment, a single and continuous slit separation structure SSS may overlap both the cell region CER and connection region CNR as shown in FIG. 4. In an embodiment, a single and continuous slit separation structure SSS may overlap both the cell region CER and connection region CNR of neighboring memory blocks (i.e., BLK1 and BLK2) as well as the boundary portions between the cell region CER and the connection region CNR of the neighboring memory blocks. In an embodiment, the first slit SLT1 and the second slit SLT2 are physically spaced apart from each other by the slit separation structure SSS as shown in FIG. 4. The slit separation structure SSS may extend in the vertical direction so that the vertical extension length thereof is equal to or longer than the vertical extension length of the first slit SLT1 and the second slit SLT2. The cross-section of the slit separation structure SSS may have an H shape. In an embodiment, the slit separation structure SSS may have a first part extending from a first memory block BLK1 to the second memory block BLK2 in a second direction Y and a second part extending from the first memory block BLK1 to the second memory block BLK2 in the second direction Y. The first part may be spaced apart from the second part, in the first direction X, by a middle part extending in the first direction X to connect the first part to the second part as, for example, as shown in FIG. 4. In an embodiment, the first part of the slit separation structure SSS may be parallel to the second part of the slit separation structure SSS in the second direction Y and the middle part of the slit separation structure SSS may connect the first part with the second part in the first direction X orthogonal to the second direction Y. In an embodiment, the middle part of the slit separation structure SSS may have a thickness T1 in the second direction Y which is greater than the thickness T2 of the first slit SLT1 and the second slit SLT2 in the second direction Y. In an embodiment the length of the first part in the second direction Y may be the same as the length of the second part in the second direction as shown in FIG. 4. In an embodiment the length of the first part in the second direction Y may be different from the length of the second part in the second direction. In an embodiment, the length of the first part in the second direction Y and the length of the second part in the second direction of the separation structure SSS may be greater than or equal to the thickness T1 of the middle part of the slit separation structure SSS. In an embodiment, the middle part of the slit separation structure may overlap the common border of the cell region CER and the connection region CNR. In other embodiments, the cross-section of the slit separation structure SSS may have any of various shapes such as a cross, a rectangle, a circle, or an ellipse etc. The thickness T1 of the slit separation structure SSS in the second direction Y may be formed to be greater than the thickness T2 of the first slit SLT1 and the second slit SLT2 in the second direction Y. For example, the first direction X may be the extension direction of the first slit SLT1 and the second slit SLT2, and the second direction Y may be a direction vertically intersecting the extension direction of the first slit SLT1 and the second slit SLT2.

An etching process of forming the first slit SLT1 and the second slit SLT2 may be performed as a dry etching process. Because the dry etching process may be performed in a plasma environment, an etching pattern may be distorted in a portion in which a charge potential difference occurs on an etching target. Here, charge potential may refer to energy in plasma attributable to the density difference between conductive layers. Because the density difference between conductive materials is maximized in the boundary portion between the cell region CER and the connection region CNR, defects in which an etching shape is bent in the etching process may occur in the boundary portion between the cell region CER and the connection region CNR. In the first embodiments of the present disclosure, the slit separation structure SSS may be formed in the boundary portion between the cell region CER and the connection region CNR. In an embodiment, the first slit SLT1 and the second slit SLT2 are not formed in the boundary portion between the cell region CER and the connection region CNR by means of the slit separation structure SSS, and thus a problem in which etching defects occur in a slit forming process may be overcome. The slit separation structure SSS may be formed of an insulating material. Further, the slit separation structure SSS may contain therein a conductive material or a semiconductor material that is capable of attracting charges. For example, the slit separation structure SSS may include a core portion formed of a conductive material or a semiconductor material, and an outer shell enclosing the core portion and formed of an insulating material.

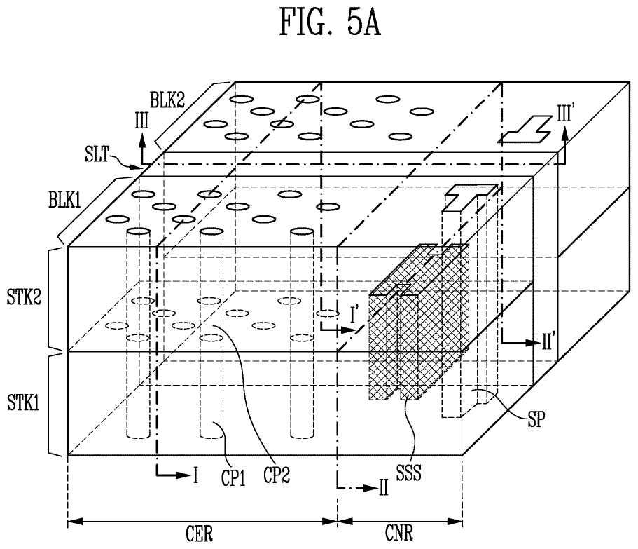

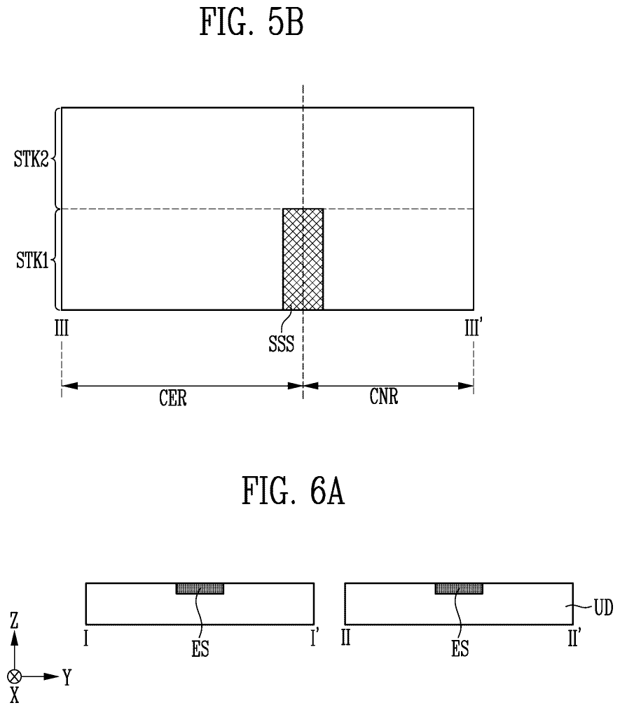

FIGS. 5A and 5B are a perspective view and a sectional view of a memory device according to a second embodiment of the present disclosure.

Referring to FIGS. 5A and 5B, the memory device may include memory blocks in which two or more multi-stacked structures are stacked. For example, each of first and second memory blocks BLK1 and BLK2 may include first and second stacked structures STK1 and STK2 that are stacked. For example, in the case of the first memory block BLK1, the second stacked structure STK2 may be stacked on the first stacked structure STK1. In the first memory block BLK1, the first and second stacked structures STK1 and STK2 may include first and second cell plugs CP1 and CP2, respectively, which extend in a vertical direction. For example, the first cell plugs CP1 may be formed in the cell region CER of the first stacked structure STK1, and the second cell plugs CP2 may be formed in the cell region CER of the second stacked structure STK2.

A slit separation structure SSS may be disposed between a boundary portion between the cell region CER and the connection region CNR of the first memory block BLK1 and a boundary portion between the cell region CER and the connection region CNR of the second memory block BLK2. The slit separation structure SSS may physically separate a slit SLT in the cell region CER and a slit SLT in the connection region CNR, which pass through the first stacked structure STK1, from each other. Further, the slit SLT passing through the second stacked structure STK2 may overlap the top of the slit separation structure SSS. That is, in the second embodiment of the present disclosure, the slit separation structure SSS may be formed such that the slit SLT is separated in a boundary portion between the cell region CER and the connection region CNR in the first stacked structure STK1, and might not be formed in the second stacked structure STK2. That is, in an embodiment, because the depth of the slit SLT having a multi-stacked structure is greater than the slit SLT having a single-stacked structure, more defects in the etching process of forming the slits SLT may occur in the first stacked structure STK1 disposed in a lower portion. In order to solve this problem, in an embodiment, the slit separation structure SSS may be disposed in the first stacked structure STK1.

FIGS. 6A, 6B, 6C, 6D, 6E, 6F, 6G, and 6H are sectional views and plan views illustrating a method of manufacturing a memory device according to a first embodiment of the present disclosure. FIGS. 6A, 6B, 6C, 6D, 6E, 6F, 6G, and 6H are sectional views and plan views taken along I and I′ shown in FIG. 5A and II and II′ shown in FIG. 5A.

Referring to FIGS. 4 and 6A, an etch stop pattern ES may be formed in a region in which a first slit SLT1, a second slit SLT2, and a slit separation structure SSS are to be formed in a lower structure UD. The lower structure UD may be a source line structure. The etch stop pattern ES may be used as a stop layer for preventing or mitigating over-etching during a subsequent etching process of forming the first slit SLT1, the second slit SLT2, and the slit separation structure SSS. The etch stop pattern ES may be formed of a conductive material such as tungsten. The etch stop pattern ES may be formed in the shape of a line extending from the cell region CER to the connection region CNR.

Referring to FIGS. 4 and 6B, a first stacked structure STK1 may be formed on the lower structure UD including the etch stop pattern ES. The first stacked structure STK1 may include first and second material layers MA1 and MA2 that are alternately stacked. The first material layers MA1 may be oxide layers, and the second material layers MA2 may be sacrificial layers to be removed in a subsequent process. For example, the second material layers MA2 may be nitride layers. The first material layers MA1 may be used as material layers which isolate gate lines from each other in the subsequent process.

Referring to FIGS. 4 and 6C, first vertical holes H1 and second vertical holes H2 that vertically pass through the first stacked structure STK1 in the cell region CER may be formed. The first vertical holes H1 may be formed in a region corresponding to the first memory block BLK1, and the second vertical holes H2 may be formed in a region corresponding to the second memory block BLK2. The first vertical holes H1 and the vertical holes H2 may be formed in a region spaced apart from the etch stop pattern ES. An etching process of forming the first vertical holes H1 and the second vertical holes H2 may be performed until a portion of the lower structure UD is exposed.

Referring to FIGS. 4 and 6D, the first vertical holes (e.g., H1 of FIG. 6C) and the second vertical holes (e.g., H2 of FIG. 6C) may be filled with a sacrificial material, and a second stacked structure STK2 may be formed on the first stacked structure STK1. The second stacked structure STK2 may be formed in the same structure as the first stacked structure STK1. For example, the second stacked structure STK2 may include first and second material layers MA1 and MA2 that are alternately stacked. Then, third vertical holes H3 and fourth vertical holes H4 that vertically pass through the second stacked structure STK2 in the cell region CER may be formed. The third vertical holes H3 and the fourth vertical holes H4 may expose the sacrificial material included in the first vertical holes (e.g., H1 of FIG. 6C) and the second vertical holes (e.g., H2 of FIG. 6C) of the first stacked structure STK1. The third vertical holes H3 and the fourth vertical holes H4 may extend to pass through the first stacked structure STK1 by removing the sacrificial material exposed through the third vertical holes H3 and the fourth vertical holes H4.

Referring to FIGS. 4 and 6E, cell plugs CP may be formed in the third vertical holes (e.g., H3 of FIG. 6D) and the fourth vertical holes (e.g., H4 of FIG. 6D) that vertically pass through the first stacked structure STK1 and the second stacked structure STK2. Each of the cell plugs CP may include a memory layer ML, a channel layer CH, and a core pillar CR. A blocking layer BX of the memory layer ML may be formed in the shape of a cylinder penetrating the first stacked structure STK1 and the second stacked structure STK2, and may be formed of an oxide layer or a silicon oxide layer. A charge trap layer CT of the memory layer ML may be formed in a cylindrical shape along an inner wall of the blocking layer BX, and may be formed of a nitride layer. A tunnel isolation layer TX of the memory layer ML may be formed in a cylindrical shape along an inner wall of the charge trap layer CT, and may be formed of an oxide layer or a silicon oxide layer. The channel layer CH may be formed in a cylindrical shape along an inner wall of the tunnel isolation layer TX, and may be formed of conductive polysilicon. The core pillar CR may be formed in the shape of a cylinder filling the channel layer CH, and may be formed of an insulating material such as an oxide layer or a silicon oxide layer.

Referring to FIGS. 4 and 6F, an opening vertically passing through the first stacked structure STK1 and the second stacked structure STK2 may be formed such that the etch stop pattern ES formed in the boundary region between the cell region CER and the connection region CNR is exposed. Thereafter, the slit separation structure SSS may be formed in the opening. The cross-section of the slit separation structure SSS may have an H shape. In other embodiments, the cross-section of the slit separation structure SSS may have any of various shapes such as a circle, an ellipse, a rectangle, and a cross.

The slit separation structure SSS may contain an insulating material, a conductive material or a semiconductor material. For example, the slit separation structure SSS may be formed by forming a liner-type insulating layer along a sidewall and a bottom surface of the opening that vertically passes through the first stacked structure STK1 and the second stacked structure STK2, and thereafter filling the opening with a conductive material or a semiconductor material. The slit separation structure SSS may be formed to include an oxide layer, a silicon oxide layer, a silicon nitride layer, a metal layer, or a polysilicon layer.

Referring to FIGS. 6G and 6H, the first slit SLT1 and the second slit SLT2 for separating the first and second memory blocks BLK1 and BLK2 from each other may be formed. In order to form the first slit SLT1 and the second slit SLT2, a trench passing through the first stacked structure STK1 and the second stacked structure STK2 on the etch stop pattern ES may be formed. The trench may be formed using a dry etching process, and more specifically, the trench may be formed by performing an anisotropic dry etching process. During the etching process of forming the trench, the slit separation structure SSS may be prevented or mitigated from being etched. The second material layers (e.g., MA2 of FIG. 6F) of the first stacked structure STK1 and the second stacked structure STK2, which are exposed through the trench, may be removed, and third material layers MA3 may be formed in spaces from which the second material layers (e.g., MA2 of FIG. 6F) are removed. The third material layers MA3 may be used as the source select line SSL, the first to i-th word lines WL1 to WLi, and the drain select line DSL of FIG. 3.

Subsequently, the first slit SLT1 and the second slit SLT2 may be formed by filling the trench with an insulating material.

The first slit SLT1 and the second slit SLT2 may be physically spaced apart from each other in the boundary portion between the cell region CER and the connection region CNR due to the slit separation structure SSS.

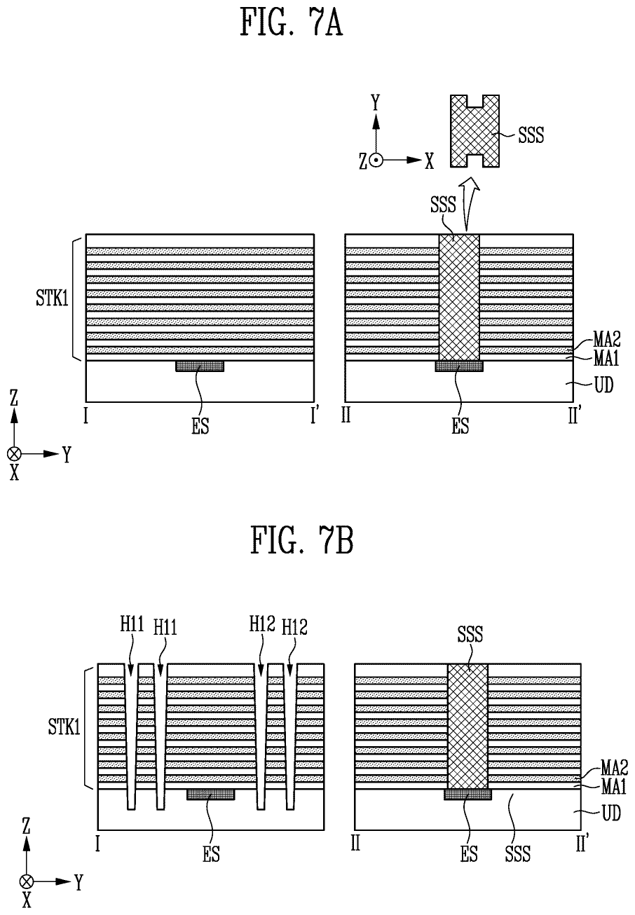

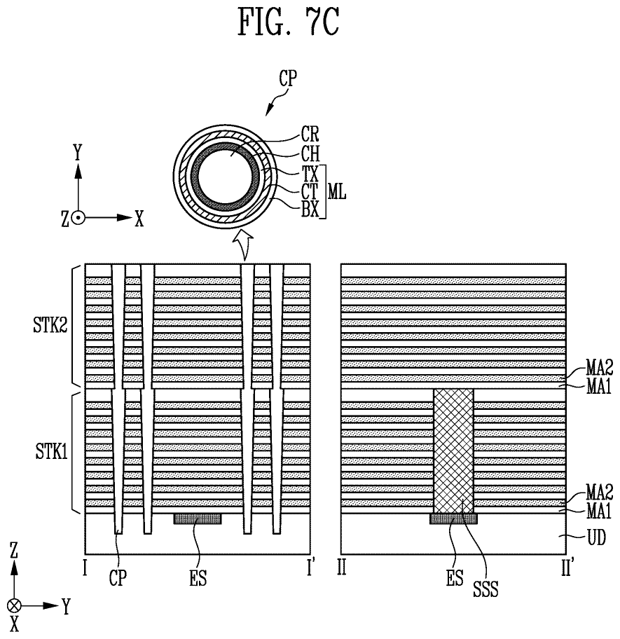

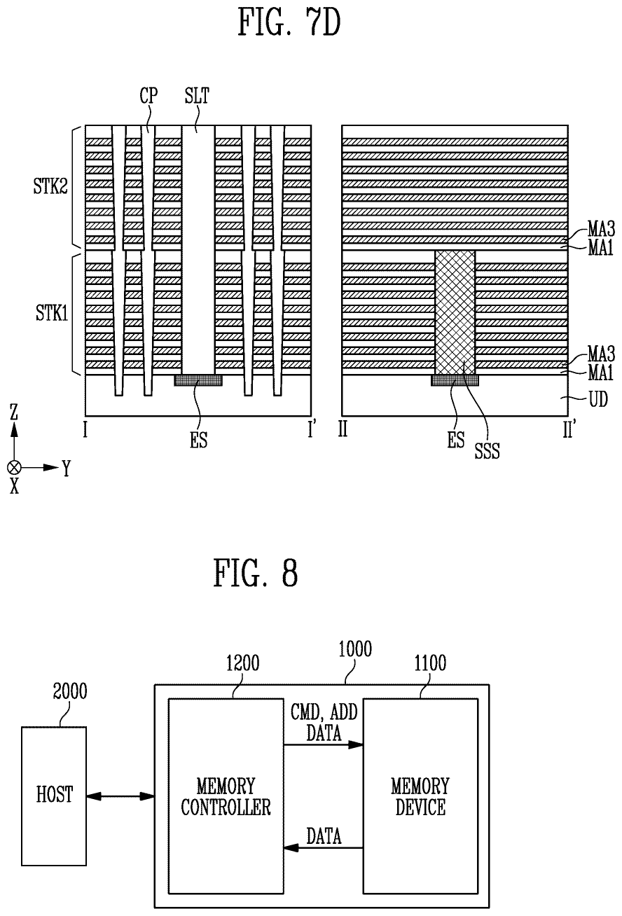

FIGS. 7A, 7B, 7C, and 7D are sectional views and plan views illustrating a method of manufacturing a memory device according to second embodiments of the present disclosure. FIGS. 7A, 7B, 7C, and 7D are sectional views and plan views taken along I and I′ shown in FIG. 5A and II and II′ shown in FIG. 5A.

Referring to FIGS. 5A and 7A, an etch stop pattern ES may be formed in a region in which a slit SLT and a slit separation structure SSS are to be formed in a lower structure UD. The lower structure UD may be a source line structure. The etch stop pattern ES may be used as a stop layer for preventing or mitigating over-etching during a subsequent etching process of forming the slit SLT and the slit separation structure SSS. The etch stop pattern ES may be formed of a conductive material such as tungsten. The etch stop pattern ES may be formed in the shape of a line extending from the cell region CER to the connection region CNR.

A first stacked structure STK1 may be formed on the lower structure UD including the etch stop pattern ES. The first stacked structure STK1 may include first and second material layers MA1 and MA2 that are alternately stacked. The first material layers MA1 may be oxide layers, and the second material layers MA2 may be sacrificial layers to be removed in a subsequent process. For example, the second material layers MA2 may be nitride layers. The first material layers MA1 may be used as material layers which isolate gate lines from each other in the subsequent process.

Subsequently, an opening vertically passing through the first stacked structure STK1 may be formed such that the etch stop pattern ES formed in a boundary portion between the cell region CER and the connection region CNR is exposed. Thereafter, the slit separation structure SSS may be formed in the opening. The cross-section of the slit separation structure SSS may have an H shape. In an embodiment, the cross-section of the slit separation structure SSS may have an H shape as indicated in FIG. 7A. In other embodiments, the cross-section of the slit separation structure SSS may have any of various shapes such as a circle, an ellipse, a rectangle, and a cross etc.

The slit separation structure SSS may contain an insulating material, a conductive material or a semiconductor material. For example, the slit separation structure SSS may be formed by forming a liner-type insulating layer along a sidewall and a bottom surface of the opening that vertically passes through the first stacked structure STK1, and thereafter filling the opening with a conductive material or a semiconductor material. The slit separation structure SSS may be formed to include an oxide layer, a silicon oxide layer, a silicon nitride layer, a metal layer, or a polysilicon layer.

Referring to FIGS. 5A and 7B, first vertical holes H11 and second vertical holes H12 that vertically pass through the first stacked structure STK1 in the cell region CER may be formed. The first vertical holes H11 may be formed in a region corresponding to the first memory block BLK1, and the second vertical holes H12 may be formed in a region corresponding to the second memory block BLK2. The first vertical holes H11 and the vertical holes H12 may be formed in a region spaced apart from the etch stop pattern ES. An etching process of forming the first vertical holes H11 and the second vertical holes H12 may be performed until a portion of the lower structure UD is exposed.

Referring to FIGS. 5A and 7C, the first vertical holes (e.g., H11 of FIG. 7B) and the second vertical holes (e.g., H12 of FIG. 7B) may be filled with a sacrificial material, and a second stacked structure STK2 may be formed on the first stacked structure STK1. The second stacked structure STK2 may be formed in the same structure as the first stacked structure STK1. For example, the second stacked structure STK2 may include first and second material layers MA1 and MA2 that are alternately stacked. Accordingly, the top of the slit separation structure SSS may be covered by the second stacked structure STK2.

Next, vertical holes vertically passing through the second stacked structure STK2 in the cell region CER may be formed. The vertical holes may expose the sacrificial material included in the first vertical holes (e.g., H11 of FIG. 7B) and the second vertical holes (e.g., H12 of FIG. 7B) of the first stacked structure STK1. The vertical holes may extend to pass through the first stacked structure STK1 by removing the sacrificial material exposed through the vertical holes.

Subsequently, cell plugs CP may be formed in the vertical holes vertically passing through the first stacked structure STK1 and the second stacked structure STK2. Each of the cell plugs CP may include a memory layer ML, a channel layer CH, and a core pillar CR. A blocking layer BX of the memory layer ML may be formed in the shape of a cylinder penetrating the first stacked structure STK1 and the second stacked structure STK2, and may be formed of an oxide layer or a silicon oxide layer. A charge trap layer CT of the memory layer ML may be formed in a cylindrical shape along an inner wall of the blocking layer BX, and may be formed of a nitride layer. A tunnel isolation layer TX of the memory layer ML may be formed in a cylindrical shape along an inner wall of the charge trap layer CT, and may be formed of an oxide layer or a silicon oxide layer. The channel layer CH may be formed in a cylindrical shape along an inner wall of the tunnel isolation layer TX, and may be formed of conductive polysilicon. The core pillar CR may be formed in the shape of a cylinder filling the channel layer CH, and may be formed of an insulating material such as an oxide layer or a silicon oxide layer.

Referring to FIGS. 5A, 5B, and 7D, a slit SLT for separating the first and second memory blocks BLK1 and BLK2 may be formed. In order to form the slit SLT, a trench passing through the first stacked structure STK1 and the second stacked structure STK2 disposed on the etch stop pattern ES and the second stacked structure STK2 disposed on the slit separation structure SSS may be formed. The trench may be formed using a dry etching process, and more specifically, the trench may be formed by performing an anisotropic dry etching process. During the etching process of forming the trench, the slit separation structure SSS may be prevented or mitigated from being etched. The second material layers (e.g., MA2 of FIG. 7C) of the first stacked structure STK1 and the second stacked structure STK2, which are exposed through the trench, may be removed, and third material layers MA3 may be formed in spaces from which the second material layers (e.g., MA2 of FIG. 7C) are removed. The third material layers MA3 may be used as the source select line SSL, the first to i-th word lines WL1 to WLi, and the drain select line DSL of FIG. 3.

Subsequently, the slit SLT may be formed by filling the trench with an insulating material. The slit separation structure SSS may physically separate a slit SLT in the cell region CER and a slit SLT in the connection region CNR, which pass through the first stacked structure STK1, from each other.

FIG. 8 is a diagram illustrating a memory system according to an embodiment of the present disclosure.

Referring to FIG. 8, a memory system 1000 may include a memory device 1100 which stores data, and a memory controller 1200 which controls the memory device 1100 under the control of a host 2000.

The host 2000 is capable of communicating with the memory system 1000 using an interface protocol, such as peripheral component interconnect-express (PCI-E), advanced technology attachment (ATA), serial ATA (SATA), parallel ATA (PATA) or serial attached SCSI (SAS). In addition, the interface protocol between the host 2000 and the memory system 1000 is not limited to the above-described examples, and may be one of various other interface protocols, such as universal serial bus (USB), multimedia card (MMC), enhanced small disk interface (ESDI), and integrated drive electronics (IDE).

The memory controller 1200 may control the overall operation of the memory system 1000, and may control data exchange between the host 2000 and the memory device 1100. For example, the memory controller 1200 may program or read data by controlling the memory device 1100 in response to a request received from the host 2000. During a program operation, the memory controller 1200 transmits a command CMD, an address ADD, and data DATA to be programmed, which correspond to the program operation, to the memory device 1100. Further, during a read operation, the memory controller 1200 may receive data DATA read from the memory device 1100, store the data DATA, and transmit the stored data DATA to the host 2000. The memory device 1100 may be implemented through the example of the memory device 100 illustrated in FIG. 1.

In an embodiment, the memory device 1100 may include a double data rate synchronous dynamic random access memory (DDR SDRAM), a low power double data rate fourth generation (LPDDR4) SDRAM, a graphics double data rate (GDDR) SDRAM, a low power DDR (LPDDR) SDRAM, a Rambus DRAM (RDRAM) or a flash memory.

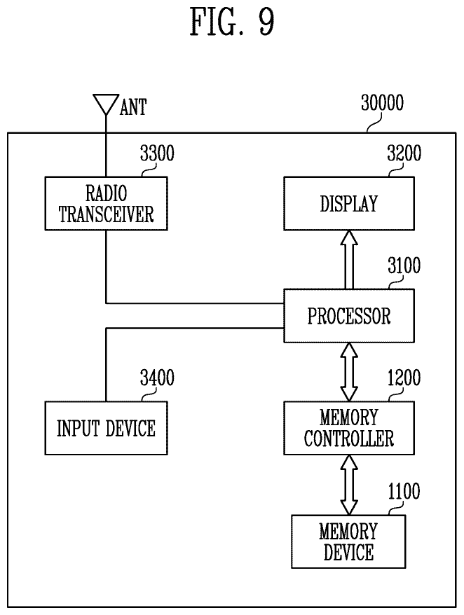

FIG. 9 is a diagram illustrating an embodiment of a memory system.

Referring to FIG. 9, a memory system 30000 may be implemented as a cellular phone, a smartphone, a tablet PC, a personal digital assistant (PDA) or a wireless communication device. The memory system 30000 may include a memory device 1100 and a memory controller 1200 that is capable of controlling the operation of the memory device 1100. The memory controller 1200 may control a data access operation of the memory device 1100, for example, a program operation, an erase operation or a read operation, under the control of a processor 3100.

Data programmed to the memory device 1100 may be output via a display 3200 under the control of the memory controller 1200.

A radio transceiver 3300 may exchange radio signals through an antenna ANT. For example, the radio transceiver 3300 may convert radio signals received through the antenna ANT into signals that can be processed by the processor 3100. Therefore, the processor 3100 may process the signals output from the radio transceiver 3300, and may transmit the processed signals to the memory controller 1200 or the display 3200. The memory controller 1200 may program the signals processed by the processor 3100 to the memory device 1100. Further, the radio transceiver 3300 may convert signals output from the processor 3100 into radio signals and output the converted radio signals to an external device through the antenna ANT. An input device 3400 may be a device that is capable of inputting a control signal for controlling the operation of the processor 3100, or data to be processed by the processor 3100, and may be implemented as a pointing device such as a touch pad or a computer mouse, a keypad or a keyboard. The processor 3100 may control the operation of the display 3200 such that data output from the memory controller 1200, data output from the radio transceiver 3300 or data output from the input device 3400 can be output via the display 3200.

In accordance with an embodiment, the memory controller 1200 capable of controlling the operation of the memory device 1100 may be implemented as a part of the processor 3100 or as a chip provided separately from the processor 3100. Further, the memory controller 1200 may be implemented through the example of the memory controller 1200 illustrated in FIG. 8, and the memory device 1100 may be implemented through the example of the memory device 100 illustrated in FIG. 1.

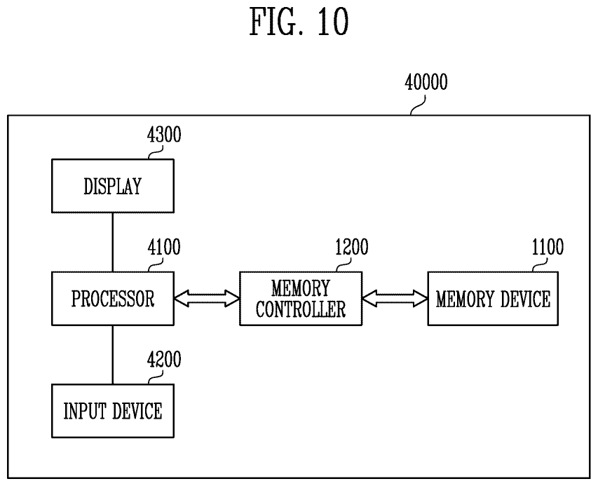

FIG. 10 is a diagram illustrating an embodiment of a memory system.

Referring to FIG. 10, a memory system 40000 may be implemented as a personal computer (PC), a tablet PC, a net-book, an e-reader, a personal digital assistant (PDA), a portable multimedia player (PMP), an MP3 player, or an MP4 player.

The memory system 40000 may include a memory device 1100 and a memory controller 1200 capable of controlling a data processing operation of the memory device 1100.

A processor 4100 may output data stored in the memory device 1100 via a display 4300 according to data input from an input device 4200. For example, the input device 4200 may be implemented as a point device such as a touch pad or a computer mouse, a keypad or a keyboard.

The processor 4100 may control the overall operation of the memory system 40000 and control the operation of the memory controller 1200. In an embodiment, the memory controller 1200 capable of controlling the operation of the memory device 1100 may be implemented as a part of the processor 4100 or as a chip provided separately from the processor 4100. Further, the memory controller 1200 may be implemented through the example of the memory controller 1200 illustrated in FIG. 8, and the memory device 1100 may be implemented through the example of the memory device 100 illustrated in FIG. 1.

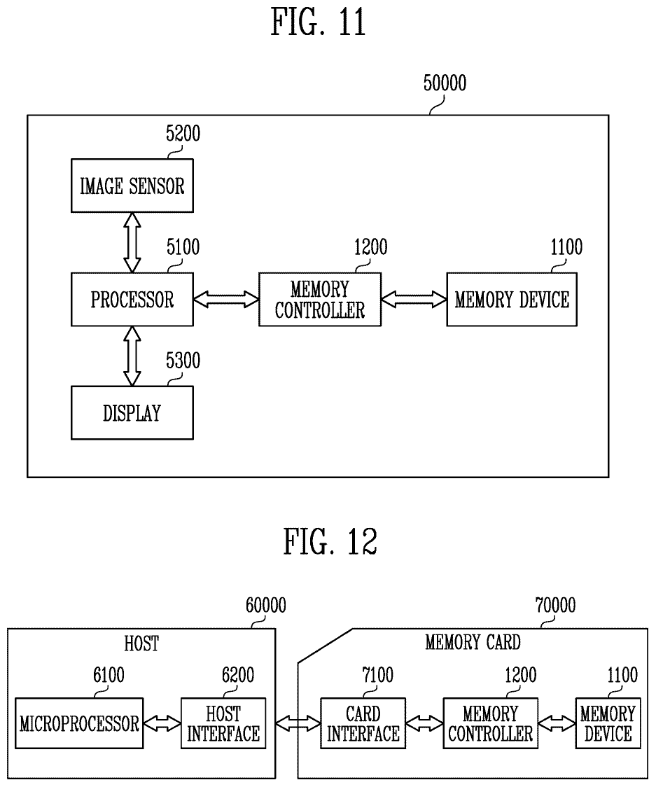

FIG. 11 is a diagram illustrating an embodiment of a memory system.

Referring to FIG. 11, a memory system 50000 may be implemented as an image processing device, for example, a digital camera, a cellular phone provided with a digital camera, a smartphone provided with a digital camera, or a tablet PC provided with a digital camera.

The memory system 50000 may include a memory device 1100 and a memory controller 1200 that is capable of controlling a data processing operation of the memory device 1100, for example, a program operation, an erase operation or a read operation.

An image sensor 5200 of the memory system 50000 may convert an optical image into digital signals, and the converted digital signals may be transmitted to a processor 5100 or the memory controller 1200. Under the control of the processor 5100, the converted digital signals may be output via a display 5300 or stored in the memory device 1100 through the memory controller 1200. Further, the data stored in the memory device 1100 may be output via the display 5300 under the control of the processor 5100 or the memory controller 1200.

In accordance with an embodiment, the memory controller 1200 capable of controlling the operation of the memory device 1100 may be implemented as a part of the processor 5100 or as a chip provided separately from the processor 5100. Further, the memory controller 1200 may be implemented through the example of the memory controller 1200 illustrated in FIG. 8, and the memory device 1100 may be implemented through the example of the memory device 100 illustrated in FIG. 1.

FIG. 12 is a diagram illustrating an embodiment of a memory system.

Referring to FIG. 12, a memory system 70000 may be implemented as a memory card or a smart card. The memory system 70000 may include a memory device 1100, a memory controller 1200, and a card interface 7100.

The memory controller 1200 may control data exchange between the memory device 1100 and the card interface 7100. In an embodiment, the card interface 7100 may be, but is not limited to, a secure digital (SD) card interface or a multimedia card (MMC) interface. Further, the memory controller 1200 may be implemented through the example of the memory controller 1200 illustrated in FIG. 8, and the memory device 1100 may be implemented through the example of the memory device 100 illustrated in FIG. 1.

The card interface 7100 may interface data exchange between a host 60000 and the memory controller 1200 according to a protocol of the host 60000. In accordance with an embodiment, the card interface 7100 may support a universal serial bus (USB) protocol and an interchip (IC)-USB protocol. Here, the card interface may refer to hardware capable of supporting a protocol which is used by the host 60000, software installed in the hardware, or a signal transmission method.

When the memory system 70000 is coupled to a host interface 6200 of the host 60000 such as a PC, a tablet PC, a digital camera, a digital audio player, a cellular phone, console video game hardware or a digital set-top box, the host interface 6200 may perform data communication with the memory device 1100 through the card interface 7100 and the memory controller 1200 under the control of a microprocessor 6100.

Various embodiments of the present disclosure may reduce differences in the electrical characteristics of memory blocks separated by a slit by preventing or mitigating defects from occurring in the slit.

What is claimed is:

1. A memory device, comprising:
a cell region and a connection region arranged adjacent to each other in a first direction;
a stacked structure formed in the cell region and the connection region;
a first slit vertically passing through the stacked structure in the cell region and extending in the first direction;
a second slit vertically passing through the stacked structure in the connection region and extending in the first direction; and
a slit separation structure vertically penetrating the stacked structure at a boundary portion between the cell region and the connection region.

2. The memory device according to claim 1, wherein the first slit and the second slit are located on an identical line and are physically spaced apart from each other by the slit separation structure.

3. The memory device according to claim 1, wherein a cross-section of the slit separation structure has an H shape, a cross shape, a rectangular shape, a circular shape or an elliptical shape.

4. The memory device according to claim 1, wherein the slit separation structure includes an insulating material, a conductive material, or a semiconductor material.

5. The memory device according to claim 1, wherein the slit separation structure comprises a core portion formed of a conductive material or a semiconductor material, and an outer shell formed of an insulating material enclosing the core portion.

6. The memory device according to claim 1, wherein the slit separation structure is configured such that a thickness of the slit separation structure in a second direction substantially orthogonal to the first direction is greater than a thickness of each of the first slit and the second slit in the second direction.

7. The memory device according to claim 1, wherein a cross-section of the slit separation structure includes a first part spaced apart from a second part in the first direction by a middle part, the middle part extending in the first direction to couple the first part to the second part, and the first and second parts extending in a second direction substantially orthogonal to the first direction.

8. A memory device, comprising:
a first memory block including a cell region and a connection region separated from each other in a first direction;
a second memory block including the cell region and the connection region separated from each other in the first direction, the second memory block being arranged adjacent to the first memory block in a second direction substantially perpendicular to the first direction;
a slit configured to separate the first and second memory blocks from each other; and
a slit separation structure vertically extending between a boundary portion between the cell region and the connection region of the first memory block and a boundary portion between the cell region and the connection region of the second memory block, and penetrating a portion of the slit.

9. The memory device according to claim 8, wherein the slit overlaps a top of the slit separation structure and the top of the slit separation structure is within the slit.

10. The memory device according to claim 8, wherein a cross-section of the slit separation structure has an H shape, a cross shape, a rectangular shape, a circular shape or an elliptical shape.

11. The memory device according to claim 8, wherein the slit separation structure includes an insulating material, a conductive material, or a semiconductor material.

12. The memory device according to claim 8, wherein the slit separation structure comprises a core portion formed of a conductive material or a semiconductor material, and an outer shell formed of an insulating material enclosing the core portion.

13. The memory device according to claim 8, wherein a cross-section of the slit separation structure includes a first part spaced apart from a second part in the first direction by a middle part, the middle part extending in the first direction to couple the first part to the second part, and the first and second parts extending in the second direction.

14. A method of manufacturing a memory device, comprising:
forming a first stacked structure on a lower structure in which a cell region and a connection region adjacent to each share a common border;
forming first holes that vertically pass through the first stacked structure in the cell region;
forming a second stacked structure on the first stacked structure;
forming second holes coupled to the first holes by vertically passing through the second stacked structure in the cell region;
forming cell plugs in the first holes and the second holes;
forming a slit separation structure that vertically penetrates the second stacked structure and the first stacked structure in the connection region; and
forming a first slit that passes through the second stacked structure and the first stacked structure in the cell region and a second slit that passes through the second stacked structure and the first stacked structure in the connection region,
wherein the first slit and the second slit are located on an identical line and are physically spaced apart from each other by the slit separation structure.

15. The method according to claim 14, wherein a cross-section of the slit separation structure is formed in an H shape, a cross shape, a rectangular shape, a circular shape or an elliptical shape.

16. The method according to claim 14, wherein the slit separation structure is formed of an insulating material, a conductive material, or a semiconductor material.

17. The method according to claim 14, wherein a cross-section of the slit separation structure includes a first part spaced apart from a second part in a first direction by a middle part, the middle part extending in the first direction to couple the first part to the second part, and the first and second parts extending in a second direction substantially orthogonal to the first direction.

18. A method of manufacturing a memory device, comprising:
forming a first stacked structure on a lower structure in which a cell region and a connection region adjacent to each other share a common border;
forming first holes that vertically pass through the first stacked structure in the cell region;
forming a slit separation structure that vertically penetrates the first stacked structure in the connection region;
forming a second stacked structure on the first stacked structure;
forming second holes coupled to the first holes by vertically passing through the second stacked structure in the cell region;
forming cell plugs in the first holes and the second holes; and
forming a slit that passes through the second stacked structure and the first stacked structure in the cell region and the connection region,
wherein the slit separation structure penetrates a portion of the slit.

19. The method according to claim 18, wherein a cross-section of the slit separation structure is formed in an H shape, a cross shape, a rectangular shape, a circular shape or an elliptical shape.

20. The method according to claim 18, wherein the slit separation structure is formed of an insulating material, a conductive material, or a semiconductor material.

21. The method according to claim 18, wherein a cross-section of the slit separation structure includes a first part spaced apart from a second part in a first direction by a middle part, the middle part extending in the first direction to couple the first part to the second part, and the first and second parts extending in a second direction substantially orthogonal to the first direction.
